(19) United States
(12) Patent Application Publication
(10) Pub. No.: US 2024/0337258 A1
(43) Pub. Date: Oct. 10, 2024

(54) Ultrasonic Pump And Applications

(71) Applicant: SONICEDGE LTD., Shoham (IL)

(72) Inventors: Mordehai Margalit, Zichron Yaaqov (IL); Sagi Chen, Haifa (IL); Mikkel Mosbæk Qvist Harteg, Smørum (DK)

(21) Appl. No.: 18/627,660

(22) Filed: Apr. 5, 2024

Related U.S. Application Data
(60) Provisional application No. 63/457,823, filed on Apr. 7, 2023.
(60) Provisional application No. 63/471,779, filed on Jun. 8, 2023.
(60) Provisional application No. 63/536,512, filed on Sep. 5, 2023.

(51) Int. Cl. F04B 45/047; H10N 30/20

(52) U.S. Cl. CPC F04B 45/047; H10N 30/2047

(57) ABSTRACT

An ultrasonic pump includes a first layer with at a membrane, a spoke and an anchor, wherein the membrane is in contact with the spoke and the spoke is in contact with at the anchor; a second layer with at least one second membrane and at least one second anchor wherein the second membrane is in contact with a second anchor and the second membrane includes at least one aperture; a third layer with at least one third membrane, at least one third spoke and at least one third anchor, wherein third membrane is in contact with at least one third spoke and said third spoke is in contact with at least one third anchor. The first, second and third membrane are vertically stacked and the first layer at least one membrane and the third layer at least one membrane are configured to be actuated to generate fluid flow.

This application is based on and claims priority from U.S. Provisional Application No. 63/457,823, filed on Apr. 7, 2023, U.S. Provisional Application No. 63/471,779 filed on Jun. 8, 2023, and U.S. Provisional Application No. 63/536,512, filed on Sep. 5, 2023. The content of each of these provisional applications is hereby incorporated by reference into this specification.

### TECHNICAL FIELD

The present disclosure generally relates to systems and methods for generating fluid flow. In some examples the system and methods of generating a fluid flow are applied as cooling devices, creating low pressure or high-pressure micro enclosures, or for generating sound.

### BACKGROUND OF THE DISCLOSURE

Prior art provides several examples of an ultrasound system to generate airflow. U.S. Ser. No. 10/609,474 describes an ultrasound system to generate airflow. The system includes a membrane; a front chamber; a back chamber; and valves to regulate the direction of flow. The membrane moves at ultrasound frequency creating pressure difference at the back or front chamber and the valves open and close to facilitate a flow to or from the pressurized back or front chamber. US20210040942 describes an alternative ultrasound system to generate airflow also termed as a MEMS pump which includes a basis structure, a membrane structure opposing the basis structure and being deflectable parallel to a surface normal of the basis structure and includes a pump chamber between the basis structure and the membrane structure wherein a volume of the pump chamber is based on a position of the membrane structure with respect to the basis structure. The MEMS pump includes a passage for letting a fluid pass into the pump chamber or exit the pump chamber, wherein the passage is arranged in-plane with respect to the pump chamber. The MEMS pump includes a valve structure coupled to the passage for connecting, in a first state, the passage to a first outer volume and for connecting, in a second state, the passage to a second outer volume. US20200051895 describes an alternative approach where one or more of the valves are passive valves promoting unidirectional flow by geometric design. US20210180723 describes an alternative approach with two membranes operating out of phase and one or more virtual valves and one or more passive valves. It is desirable to achieve higher fluid flow rates, higher back flow pressures, and lower operating power for ultrasonic pumps. In this disclosure we describe an alternative ultrasonic pump architecture providing enhanced performance over existing solutions.

### Glossary

“acoustic signal”—as used in the current disclosure means a mechanical wave traversing either a gas, liquid or solid medium with any frequency or spectrum portion between 10 Hz and 10,000,000 Hz.

“ultrasound” or “ultrasonic”—as used in the current disclosure means of acoustic frequencies above 20,000 Hz.

“ultrasound pump” or “ultrasonic pump” or “pump” or “device”—as used in the current disclosure means a pump configured to induce fluid flow at rates from constant flow to alternating flows at rates up to 400 KHz, and operating at minimum displacement rate of greater than 20,000 times a second.

“audio” or “audio spectrum” or “audio signal”—as used in the current disclosure means an acoustic signal or portion of an acoustic signal with a frequency or spectrum portion between 10 Hz and 40,000 Hz.

“speaker” or “pico speaker” or “micro speaker” or “nano speaker”—as used in the current disclosure means a device configured to generate an acoustic signal with at least a portion of the signal in the audio spectrum.

“membrane”—as used in the current disclosure means a flexible structure constrained by at least one point.

“spoke”—as used in the current disclosure means a flexible structure connected on one side to a membrane and on second side to an anchor.

“anchor”—as used in the current disclosure means a structure defining the distance between a membrane and another structure element or layer.

“acoustic medium”—as used in the current disclosure means any of but not limited to; a bounded region in which a material is contained in an enclosed acoustic cavity; an unbounded region where in which a material is characterized by a speed of sound and unbounded in at least one dimension. Examples of acoustic medium include but are not limited to; air; water; ear canal; closed volume around ear; air in free space; air in tube or other acoustic channel.

### SUMMARY

Some embodiments of the present disclosure may generally relate to ultrasonic pump that includes at least two membranes and a separator, where a first membrane is located on one side of the separator and a second membrane is located on opposite side of separator. In a further example the ultrasonic pump comprising of at least two membranes and a separator is configured as a centrifugal pump. The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several embodiments in accordance with the disclosure and are therefore not to be considered limiting of its scope, the disclosure will be described with additional specificity and detail through use of the accompanying drawings.

FIG. 1A is an example of a single cell of an ultrasonic pump;

FIG. 1B is an example of a cross section of a single cell of an ultrasonic pump;

FIG. 2A is an example of a cross section of the membranes in a single cell of an ultrasonic pump during membrane movement;

FIG. 2B is an alternative example where enclosed volume is reduced;

FIG. 3A is one example of membrane movement where the membranes are actuated in phase;

FIG. 3B describes an alternative example where first membrane is actuated at 90° phase difference in respect to third membrane;

FIG. 3C describes an alternative example where first membrane is actuated at 180° phase difference in respect to third membrane;

FIG. 3D describes an alternative example where first membrane is actuated at 270° phase difference in respect to third membrane;

FIG. 4A is a graph showing the enclosed volume dimension along with ratio of first fluid conduit height to second fluid conduit height and pressure in the enclosed volume for a phase difference of 90°;

FIG. 4B is a graph showing the enclosed volume dimension along with ratio of first fluid conduit height to second fluid conduit height and pressure in the enclosed volume for a phase difference of 0°;

FIG. 4C is a graph showing the enclosed volume dimension along with ratio of first fluid conduit height to second fluid conduit height and pressure in the enclosed volume for a phase difference of 180°;

FIG. 5 is an example of alternative membrane and spoke configurations.

FIG. 6 is an alternative example of the configuration of three layers for a cell of an ultrasonic pump;

FIG. 7 is an example of top view of an array configured of a plurality of cells of FIG. 1A;

FIG. 8 is an example of a top view of an array configured of a plurality of cells of FIG. 6;

FIG. 9A is an example of a lumped element description of the ultrasonic pump;

FIG. 9B is an example of a lumped element description of the acoustic portion of the ultrasonic pump.

### DETAILED DESCRIPTION OF EXAMPLE EMBODIMENTS

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other examples may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure. This disclosure is drawn, inter alia, to methods, apparatus, computer programs, and systems of generating an audio signal.

In some examples, an ultrasonic pump includes at least three membranes. A first and third membrane configured to define at least a first and second fluid enclosure and a second membrane configured to define in combination with the first membrane a first fluid conduit, to define with the third membrane a second fluid conduit and to separate between fluid on one side of ultrasonic pump to second side of ultrasonic pump and where the fluid flow is from one side of ultrasonic pump, through first fluid conduit to fluid enclosure to second fluid conduit to second side of ultrasonic pump. In some examples mechanical resonance frequency of second membrane is higher than mechanical resonance frequency of either first or third membrane. In further examples first and third membrane are actuated using any of but not limited to; electrostatic actuation; piezoelectric actuation; thermoelectric actuation. The actuation is configured to move the first membrane towards the second membrane and the third membrane towards the second membrane. The change in fluid volume enclosed between first and third membrane induces a pressure change and fluid venting. The ratio of fluid venting between first and second movement fluid conduit is determined by the ratio of acoustic impedance of first and second fluid conduit. Acoustic impedance of fluid conduit is determined by distance between second membrane and first or second membrane respectively and overlap between second membrane and first or second membrane respectively.

In embodiments, the membrane is driven by an electric signal that oscillates at a frequency Ω and hence moves at b Cos(2π*Ωt), where b is the amplitude of the membrane movement, and t is time. The electric signal is further modulated by a portion that is derived from an audio signal a(t). The acoustic signal is characterized as:

$$s ( t ) = ba ( t ) Cos ( 2 π * Ω t ) \qquad ( 1 )$$

Applying a Fourier transform to Equation (1) results in a frequency domain representation:

$$S ( f ) = b / 2 * [ A ( f - Ω ) + A ( f + Ω ) ] \qquad ( 2 )$$

Where A(f) is the spectrum of the audio signal. Equation (2) describes a signal with an upper and lower side band around a carrier frequency of Ω. Applying to the acoustic signal of Equation (1) an acoustic modulator operating at frequency Ω results in:

$$S ( t ) = ba ( t ) Cos ( 2 π * Ω t ) ( I + m Cos ( 2 π * Ω t ) ) \qquad ( 3 )$$

Where l is the loss of the modulator and m is the modulation function and due to energy conservation l+m<1. In the frequency domain:

$${S}^{′} ( f ) = b / 4 * [ mA ( f ) + mA ( f + 2 Ω ) + A ( f - Ω ) + A ( f + Ω ) ] \qquad ( 4 )$$

Where b/4*m A(f) is an audio signal. The remaining terms are ultrasound signals where m A(f+2Ω) is at twice the modulation frequency and A(f−Ω)+A(f+Q) is the original unmodulated signal. Additional acoustic signals may be present due to any but not limited to the following; ultrasound signal from the shutter movement; intermodulation signals due to nonlinearities of the acoustic medium; intermodulation signals due to other sources of nonlinearities including electronic and mechanical.

In a further example the audio signal is enhanced by acoustic radiation pressure of the ultrasound signal. This is a new approach to audio generation where the audio system generates an ultrasound signal. The ultrasound signal exerts a radiation force on surfaces on which it impinges including the Tympanic membrane (ear drum). By modulating the ultrasound signal the radiation force magnitude can be changed, thereby effecting mechanical movement of the Tympanic membrane which is registered as sound by the ear (and brain). The radiation pressure of an acoustic signal is well documented and given as:

$$P = α E = α \frac{{p}^{2}}{ρ {c}^{2}} \qquad ( 5 )$$

Where P is the radiation pressure, and where E, p, ρ, and c are energy density of the sound beam near the surface, acoustic pressure, density of the sound medium, and the sound velocity, respectively. α is a constant related to the reflection property of the surface. If all the acoustic energy is absorbed on the surface, α is equal to 1, while for the surface that reflects all the sound energy, α is 2. The sound power E carried by the beam is E=W/c where W is the power density of the transducer. In one example to effect an audio sensation at the ear drum an ultrasound signal is modulated with an audio signal. The audio signal causes changes in the acoustic radiation force which are registered as an audio signal by the ear. In one non limiting example the audio is AM modulated on the ultrasound carrier:

$$S ( t ) = Cos ( 2 π * Ω t ) ( I + ma ( t ) ) \qquad ( 6 )$$

E is proportional to m a(t) and the changes in the radiation force P are proportional to m a(t) resulting in movement of the eardrum which is proportional to m a(t). Hence an ultrasound speaker can generate sound using any or both methods described above. In one example the methods are used intermittently, in another example the methods are used concurrently, in another example only modulation or only radiation force are used.

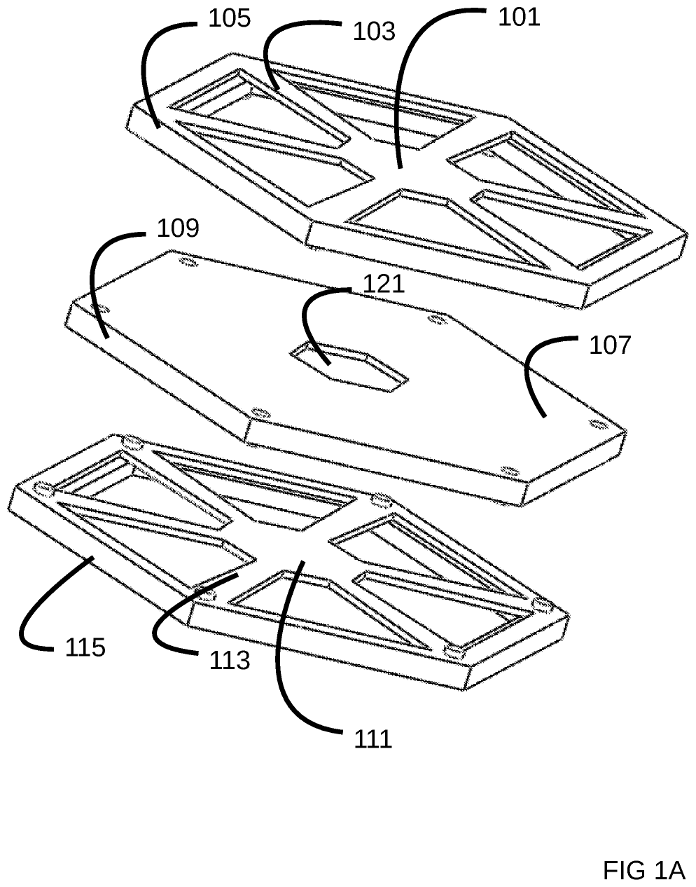

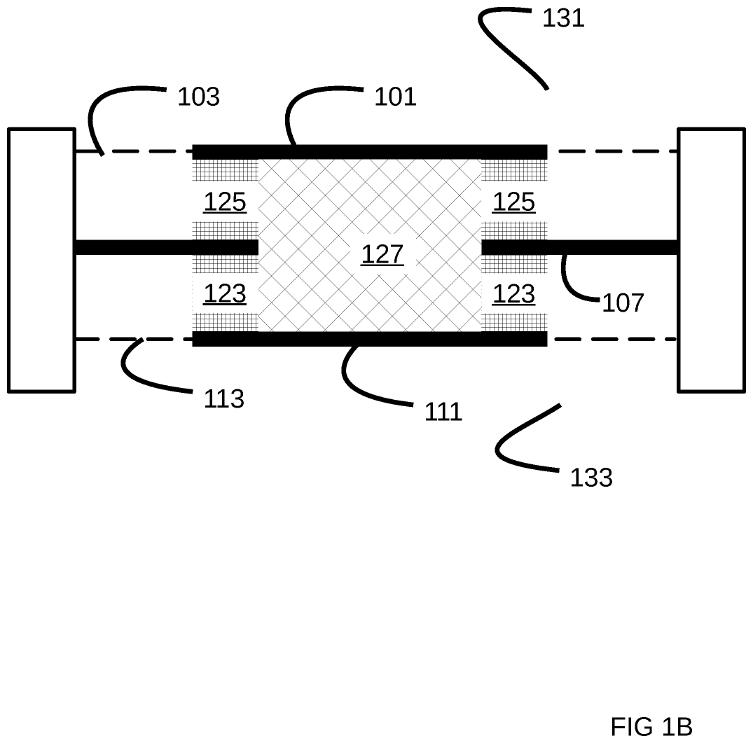

FIG. 1A is an example of a single cell of an ultrasonic pump. In a further example an ultrasonic pump includes a plurality of cells. The cell is further comprised of a first membrane (101) a second membrane (107) and third membrane (111) where the membranes are aligned, the second membrane (107) is configured with an aperture (121) aligned with first membrane (101) and third membrane (111). The first membrane (101) and third membrane (111) define a fluid enclosure with a first fluid conduit defined by the overlap between first membrane (101) and second membrane (107), a second fluid conduit defined by the overlap between the third membrane (111) and second membrane (107) and to separate between fluid on one side of ultrasonic pump to second side of ultrasonic pump. The cell is comprised of a first membrane (101), one or more spokes (103) and one or more anchors (105). A resonance frequency of the cell is defined by the square root of the spring constant of the membrane (101) divided by the effective mass of the membrane (101) and spokes (103). The spring constant is defined by the length, shape and thickness of spoke (103). The effective mass of the membrane (101) is obtained by integrating over the mass and radius of the membrane (101) and spoke (103) material. A spoke (103) is connected to an anchor (105) providing a reference height from second membrane (107) and first membrane (101). The cell is further comprised of a third membrane (111), one or more spokes (113) and one or more anchors (115). A resonance frequency of the cell is defined by the square root of the spring constant of the third membrane (111) divided by the effective mass of the third membrane (111) and spokes (113). The spring constant is defined by the length, shape, stiffness, moment of inertia and or thickness of spoke (113). The effective mass of the membrane (111) is obtained by integrating over the mass and radius of the membrane (101) and spoke (103) material. A spoke (113) is connected to an anchor (109) providing a reference height from second membrane (107) and first membrane (101). Additional anchors (115) are located above or below membranes (101, 111) further defining the height of membranes from further layers or structures.

FIG. 1B is an example of a cross section of a single cell of an ultrasonic pump. Spokes (103, 113) are depicted as a dashed line. First membrane (101) and third membrane (111) define a volume (127) with an enclosed fluid. A first fluid conduit (125) is defined by the overlap between first membrane (101) and second membrane (107). A second fluid conduit (123) is defined by the overlap between third membrane (111) and second membrane (107). Second membrane separates between fluid on one side of ultrasonic pump (131) and second side of ultrasonic pump (133) and fluid flow is from one side of ultrasonic pump (131), through first fluid conduit (125) to fluid enclosure (127) to second fluid conduit (123) to second side of ultrasonic pump (133). In an alternative example fluid flow is reversed. In a further alternative example, fluid is ejected or drawn from first and second fluid conduit (123, 125), the ratio of fluid in each conduit is the ratio of the conduit's acoustic impedance. In one example, the length of both conduits is equal and the ratio between fluid flow is proportional to the ratio of the conduits cross section. Examples of membrane material include but are not limited to; conductive material; piezo electric material; resistive material. Examples of conductive material include but are not limited to; metals; graphene; carbon nanotubes; polySi; Ge; Ga; semiconducting materials or combinations or layers of these materials. Examples of metals include but are not limited to Ni; Au; Ag; Al; Cu; Ti; Mo; Cr or combinations or alloys which include these metals. Examples of piezo electric materials include but are not limited to; AlN; AlScN; PZT; KNN; GaN or combinations of these materials. Examples of membrane actuation include: Electrostatic actuation where one voltage signal is applied on first membrane (101) and a second voltage signal is applied on third membrane (111) and second membrane (107) is grounded or connected to a third voltage signal. A voltage difference between membranes induces membrane movement; Piezo electric actuation where a voltage difference across a piezo electric material induces material deformation and membrane movement. In a further example first membrane (101) and third membrane (111) are comprised of a stack of bottom electrode; piezo electric material; and top electrode. In a further non limiting example second membrane (107) is configured to be static and comprised of dielectric; electric or piezo electric material. Membranes (101, 107, 111) are characterized with a mechanical resonant frequency f₁, f₂, f₃, respectively. At actuation of the respective membrane at a resonance frequency the displacement of the membrane will be maximal and determined by actuation level and, resonance frequency and membrane damping. In a further example f₁ and f₃ are similar and f₂ is larger. In a further example and but not limited to; |f₁-f₃|<10,000 [Hz] and f₂>max{f₁, f₃}+30,000 [Hz]; |f₁-f₃|<30,000 [Hz] and f₂>max{f₁, f₃}+50,000 [Hz]; |f₁-f₃|<50,000 [Hz] and f₂>max{f₁, f₃}+50,000 [Hz]; |f₁-f₃|<150,000 [Hz] and f₂>max{f₁, f₃}+150,000 [Hz]. Examples of first and third membrane (101, 111) shape include but are not limited to shapes bounded by; a circle; rectangular; triangle; hexagon; hectogon; heptagon; octagon. Examples of first and third membrane (101, 111) shape bounded by larger circle with a diameter length included but not limited to; less than 10 microns; 10 to 20 microns; 20 to 30 microns; 30 to 40 microns; less than 100 microns; less than 200 microns; less than 1,000 microns. Examples of second membrane (107) aperture (121) shape include but are not limited to shapes bounded by; a circle; rectangular; triangle; hexagon; hectogon; heptagon; octagon; pentagon or regular shape. Examples second membrane (107) aperture (121) shape bounded by larger circle with a diameter length included but not limited to; less than 10 microns; 10 to 20 microns; 20 to 30 microns; 30 to 40 microns; less than 100 microns; less than 200 microns; less than 1,000 microns. In a further example the minimum overlap between first or third membrane (101, 111) and the second membrane (107) due to the aperture is any of but not limited to: at least 100 nm; at least 1 micron; at least 3 microns; at least 6 microns; at least 10 microns; at least 50 microns; at least 300 microns.

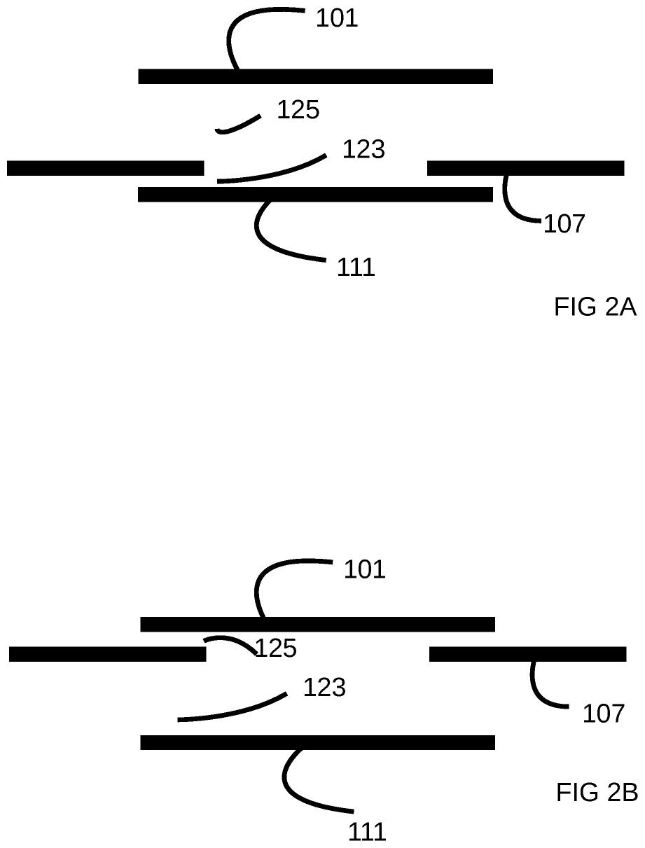

FIG. 2A is an example of a cross section of the membranes (101, 107, 111) in a single cell of an ultrasonic pump during membrane movement. First membrane (101) and third membrane (111) are actuated by two electric signals. In one example the electric signals are periodic or quasi periodic. In an alternative example at least one of the signals is periodic and the second signal is a band limited signal modulated by a periodic signal. In an alternative example both signals are a band limited signal modulated by a periodic signal. In one example the periodic signals actuating the membranes are driven with a constant or time varying phase difference between them. One non limiting example of actuation includes driving both membranes with a periodic signal with a constant phase difference between actuation signals. For a phase difference of 0 rad, the membranes move in phase and the volume of fluid enclosed between membranes remains constant. For other phase differences the volume of fluid enclosed between the membranes changes and the pressure of the enclosed fluid will change in relation to the change of the volume. We describe one non limiting example; volume is reduced; pressure of enclosed fluid increases; fluid is ejected from enclosed volume through fluid conduit ports (FIG. 1B. 123, 125) to surroundings where fluid ejection ratio is determined by fluid conduit port (FIG. 1B. 123, 125) cross section ratio. An alternative non limiting example; volume is increased; pressure of enclosed fluid decreases; fluid is drawn from surroundings through fluid conduit ports (FIG. 1B. 123, 125) to enclosed volume where fluid drawing ratio is determined by fluid conduit port (FIG. 1B. 123, 125) cross section ratio. In FIG. 2A volume is reduced, and fluid is ejected where the cross section of second fluid conduit (123) is smaller than cross section of first fluid conduit (125) resulting in larger ejection from first fluid conduit (125). FIG. 2B is an alternative example where enclosed volume is reduced, and fluid is ejected where the cross section of second fluid conduit (123) is larger than cross section of first fluid conduit (125) resulting in larger fluid ejection from second fluid conduit (123). In one example membranes have are similar and the structure including anchor heights and overlap is symmetric. In an alternative example the structure is not symmetric and any of but not limited to membrane shape, membrane area, overlap, anchor height, membrane thickness, membrane resonance frequency, membrane displacement, may be different in first and third membrane.

The dynamics of the membranes are defined by the interaction of a driving force; mechanical dynamics of the membrane; and fluid membrane interaction. Examples of driving force include but are not limited to electrostatic; thermoelectric or piezo electric. Examples of mechanical dynamics include but are not limited to; second order mechanical system; second order mechanical system with damping; higher order mechanical system. The mechanical dynamics are configured to include at least one resonance frequency for each membrane. The membrane dynamics are simulated using either a computational fluid dynamics (CFD) model or a simplified coupled differential equation describing mechanical movement and membrane fluid coupling. One example of the coupled equations with only second order dynamics for the membranes is described in equations (7) to (10) includes but is not limited to:

$${\ddot{x}}_{1} + {b}_{1} {\dot{x}}_{1} + {k}_{1} {x}_{1} = {F}_{1} ( t ) + {FP}_{1} \qquad ( 7 )$$

$${\ddot{x}}_{2} + {b}_{2} {\dot{x}}_{2} + {k}_{2} {x}_{2} = {F}_{2} ( t ) + {FP}_{2} \qquad ( 8 )$$

$${\ddot{x}}_{3} + {b}_{3} {\dot{x}}_{3} + {k}_{3} {x}_{3} = {F}_{3} ( t ) + {FP}_{3} \qquad ( 9 )$$

$$\ddot{P} + {b}_{p} \dot{P} + {k}_{p} P = {FP}_{p} \qquad ( 10 )$$

Where the index (1,2,3) refers to first, second or third membrane, bₓ is the damping coefficient, kₓ is the spring coefficient, Fₓ is the actuation force, FPₓ is the fluid membrane interaction. Equation (4) describes the second order dynamics of the fluid enclosed between the membranes where bₚ and kₚ are defined by the membrane displacement and FP_{P} is the aggregate membrane fluid interaction. Equations (1-4) describe the action of membranes to generate fluid flow \dot{P}.

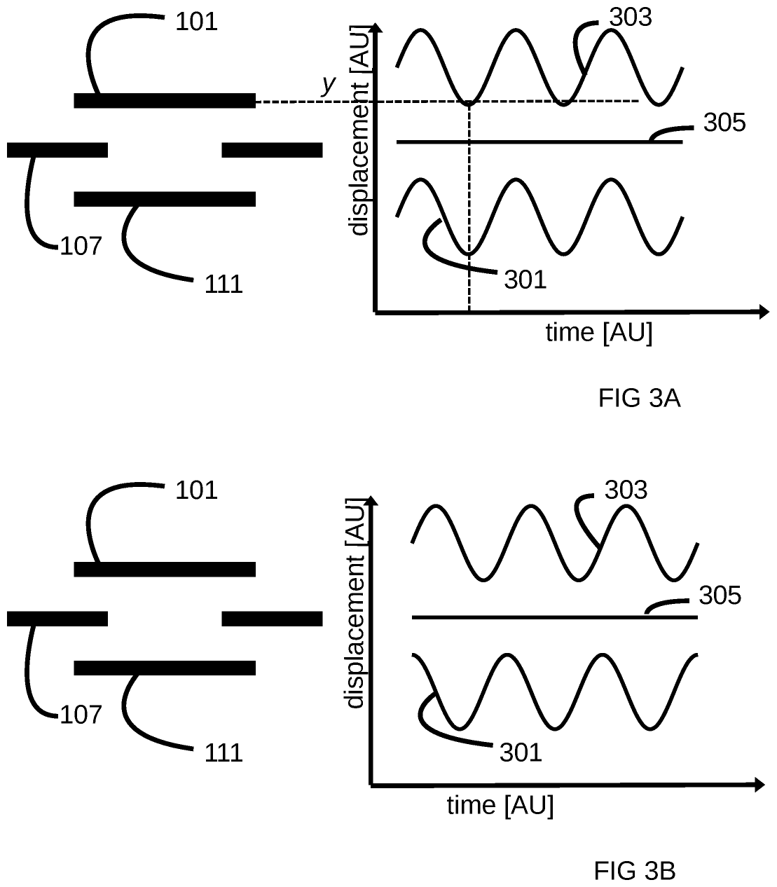

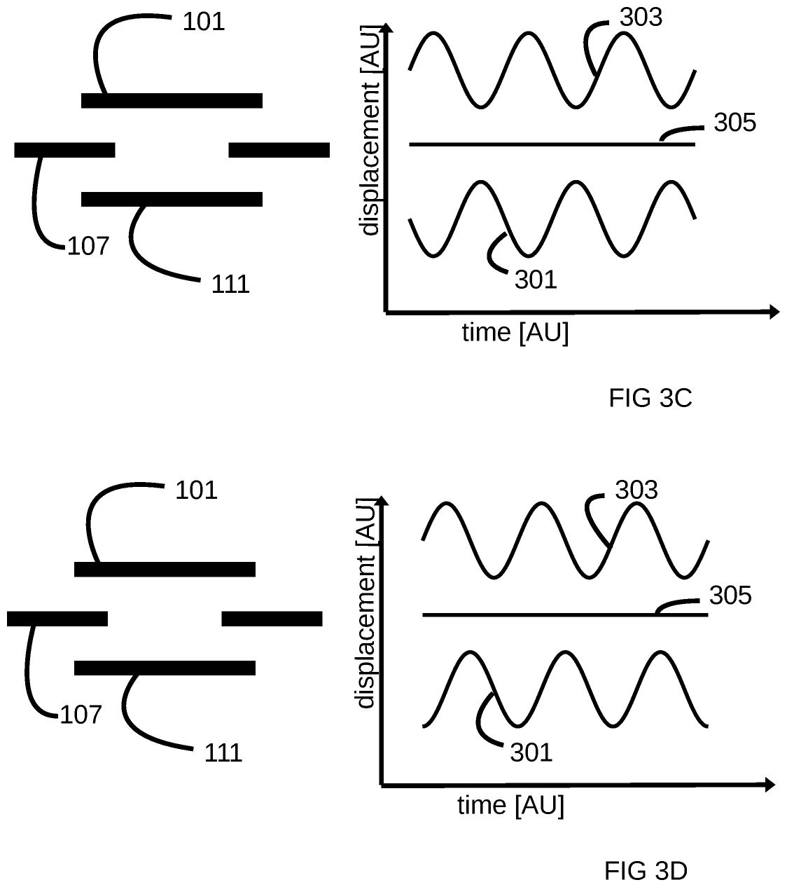

FIG. 3A is one example of membrane movement where the membranes are actuated in phase. Membrane fluid interaction are neglected to simplify the dynamic explanation. While the principle of the device is contained without fluid membrane interaction, in contrast to state of art devices, in this device membrane fluid interaction plays an important role in the performance of the device by adapting membrane dynamics to enhance flow and reduce artifacts. Device is described by first membrane (101), second membrane (107) and third membrane (111). Membrane displacement is described by first trace (303), second trace (305), and third trace (301) respectively, where the trace (303, 305, 301) value y on the y axis (displacement) represents the location of at least a portion of the respective membrane (101,107,111) at time t. In one example the actuation is harmonic and the resulting displacement is harmonic. In a further example the actuation is harmonic and the resulting displacement includes one or more harmonic frequencies as a result of nonlinearities in membrane movement and of membrane and fluid interaction. In a further example the actuation includes a modulated harmonic signal and the resulting displacement includes a modulated harmonic signal and one or more harmonic frequencies as a result of nonlinearities in membrane movement and of membrane and fluid interaction. Any of membranes (101, 107, 111) are actuated by any of but not limited to; electrostatic actuation; piezo electric actuation; thermos electric actuation. In one non limiting example, first and third membrane are actuated by a harmonic signal resulting in at least a harmonic at the actuation frequency (303, 305, 307). In a further example, resonance frequency of second membrane (107) is configured to be higher than either first or third membrane (101, 111) by configuring second membrane (107) with a stiffer spring or providing membrane with less compliance. As a result of such configuration second membrane is comparatively static (305) regardless of membrane fluid interaction or in electrostatic actuation most of the movement will be in the first or third membrane since their compliance or spring constant is smaller. First membrane (101) is actuated in phase with third membrane (111) resulting in first trace (303) in phase with third trace (301). FIG. 3B describes an alternative example where first membrane (101) is actuated at 90° phase difference in respect to third membrane (111) resulting in first trace (303) at 90° phase difference with third trace (301). FIG. 3C describes an alternative example where first membrane (101) is actuated at 180° phase difference in respect to third membrane (111) resulting in first trace (303) in at 180° phase difference with third trace (301). FIG. 3D describes an alternative example where first membrane (101) is actuated at 270° phase difference in respect to third membrane (111) resulting in first trace (303) in at 270° phase difference with third trace (301). The relative movement of the first and third membranes (101, 111) defines an enclosed volume and the relative movement of first and second membranes (101, 107) defines the height of a first fluid conduit and the relative movement of third and second membranes (111, 107) defines the height of a second fluid conduit.

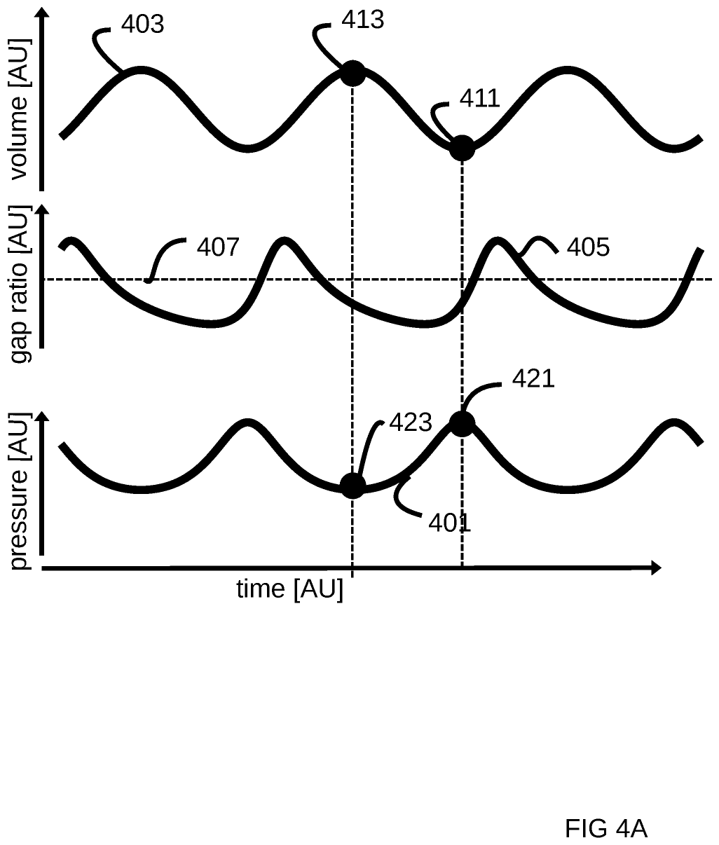

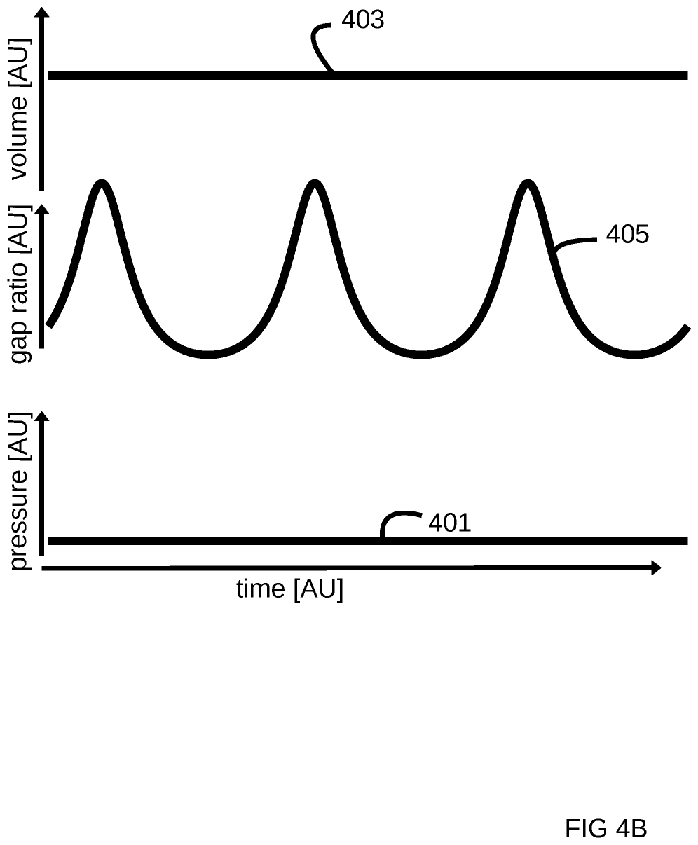

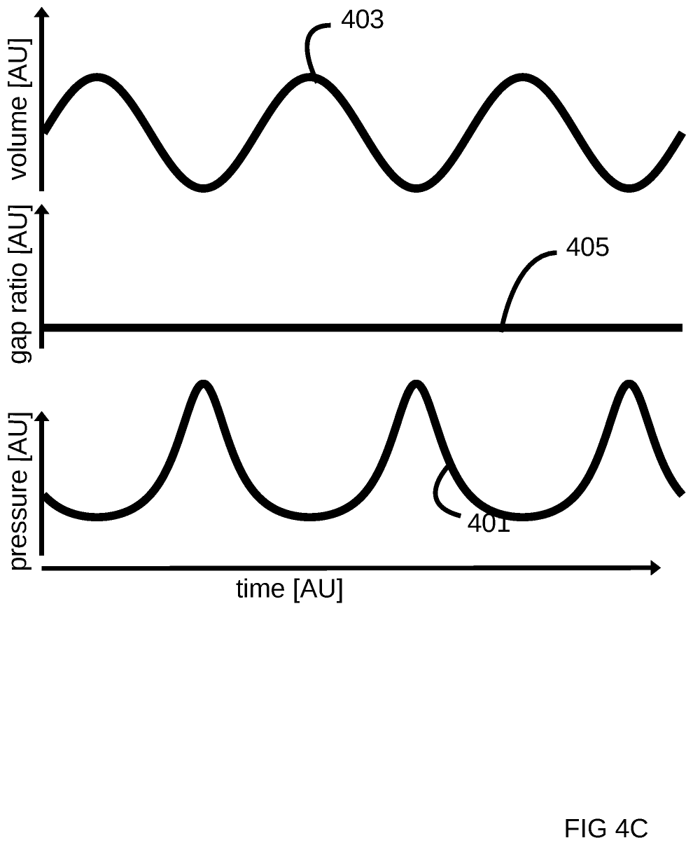

FIG. 4A is a graph showing the enclosed volume dimension (405) along with ratio of first fluid conduit height to second fluid conduit height (403) and pressure in the enclosed volume (401). The movement of the membranes (FIG. 3B 101, 107, 111) for FIG. 4A are depicted in FIG. 3B for an actuation with a phase difference of 90°. When first membrane (FIG. 3B, 101) is moving towards third membrane (FIG. 3B, 111) and or third membrane (FIG. 3B, 111) is moving towards first membrane (FIG. 3B, 101) the height of the enclosed volume is reduced and the enclosed volume is reduced (411). When membranes are moving away from each other, enclosed volume is increased (413). Increase of enclosed volume (413) results in decrease of pressure (423), and decrease of enclosed volume (411) results in increase of pressure (421). When pressure increases (421) fluid is ejected from enclosed volume through first and second fluid conduits where the ratio of fluid ejected from each conduit is determined by the cross-section ratio of the fluid conduits (405). When the ratio is greater than unity (407), a larger portion of fluid is ejected from first fluid conduit (FIG. 1B 125) than second fluid conduit (FIG. 1B 123). When the ratio is smaller than unity (407), a smaller portion of fluid is ejected from first fluid conduit (FIG. 1B 125) than second fluid conduit (FIG. 1B 123). The membrane movement action described in FIG. 4A results in a maximal pressure when a first fluid conduit (FIG. 1B 125) is larger than second fluid conduit (FIG. 1B 123), and minimum pressure when second fluid (FIG. 1B 123) conduit is smaller than first fluid conduit (FIG. 1B 125). Hence fluid is drawn through second fluid conduit (FIG. 1B 123), through enclosed volume (FIG. 1B 127) and through first fluid conduit (FIG. 1B 125) in a continuous manner providing a pump action. In an alternative example the movement of the membranes (FIG. 3A 101, 107, 111) for FIG. 4B are depicted in FIG. 3A for an actuation with a phase difference of 0°. In this example, the enclosed volume is constant (405), and hence also the pressure (401) of enclosed volume is constant. While the conduit ratio changes (403), there is no pressure difference driving the fluid and in for this example there is no fluid flow. In an alternative example the movement of the membranes (FIG. 3C 101, 107, 111) for FIG. 4C are depicted in FIG. 3C for an actuation with a phase difference of 180°. In this example, the enclosed volume changes over time (403) resulting in pressure changes (401) of the enclosed volume. However, conduit ratio (405) is constant as both first and third membrane move towards second membrane at same time due to 180° phase difference. While there is a pressure difference driving the fluid, the conduit ratio (405) is constant and the same amount of fluid is drawn or injected from first and second fluid conduit resulting in zero total fluid flow and no pump action. Movement of the membranes (FIG. 3D 101, 107, 111) with a phase difference of 270° will result in a reversal of flow direction compared to 90° phase difference as described in FIG. 4A. In an alternative configuration, rather than changing the volume between membranes and ejecting fluid through the fluid channels, the membranes are configured to impart momentum on the fluid in the cavity. The relative phase between membranes defines the net momentum imparted in each cycle. The aggregate net momentum is the fluid movement from one to second side of ultrasonic pump. This view point complements the previous description and relates the ultrasonic pump to a type of pump category termed centrifugal pumps. As in a centrifugal pump, the pump action is facilitated by momentum transfer rather than by induced pressure. This implies larger flow rate than a comparable pressure ultrasonic pressure-based pumps that appear in the literature. A further advantage of a centrifugal pump is that there is no need for valves, virtual valves or uni-directional orifices and hence the previously mentioned channels may be reduced or even omitted in some non-limiting designs. In any case the pump action occurs even when one or more valve is partially closed and the required pump power is proportional to the actual flow. Another aspect distinguishing a centrifugal pump from a displacement pump is that the flow can be configured to be constant or slowly varying as opposed to a displacement pump where the flow is defined in quanta of the displaced volume.

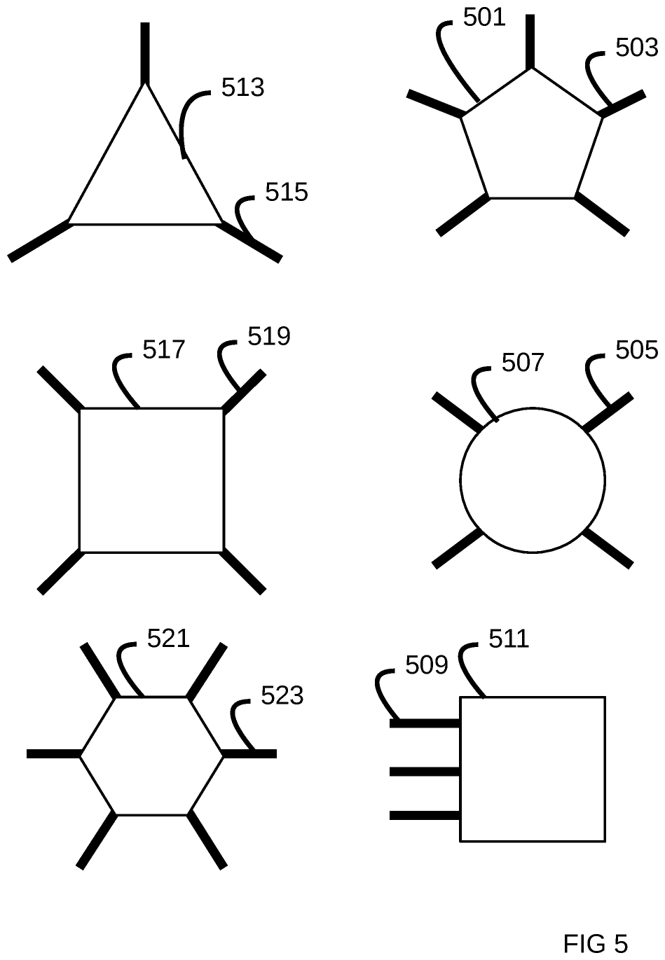

FIG. 5 is an example of alternative membrane (FIG. 1A 101, 111) and spoke (FIG. 1A 103, 113) configurations. Examples include but are not limited to; a pentagon (501) with at least one spoke (503); a circle (507) with at least one spoke (505); a rectangle (511) with at least one spoke (509); a triangular shaped membrane (513) and at least one spoke (515); a square (517) with at least one spoke (519); a hexagon (521) with at least one spoke (523). The at least one spoke (505, 515, 519, 523) or more can be distributed symmetrically around a membrane (507, 511, 513, 517, 521); In another example a spoke (503, 505, 515, 519, 523) extends from at least one corner of a membrane (501, 507, 513, 517, 521). In an alternative example a spoke (509) extends from at least one member of the enclosing perimeter of a membrane (511). An aperture (FIG. 1A 121) is configured for a membrane where the aperture (FIG. 1A 121) is smaller than a corresponding membrane (501, 507, 511, 513, 517, 521) by an overlap dimension as previously defined.

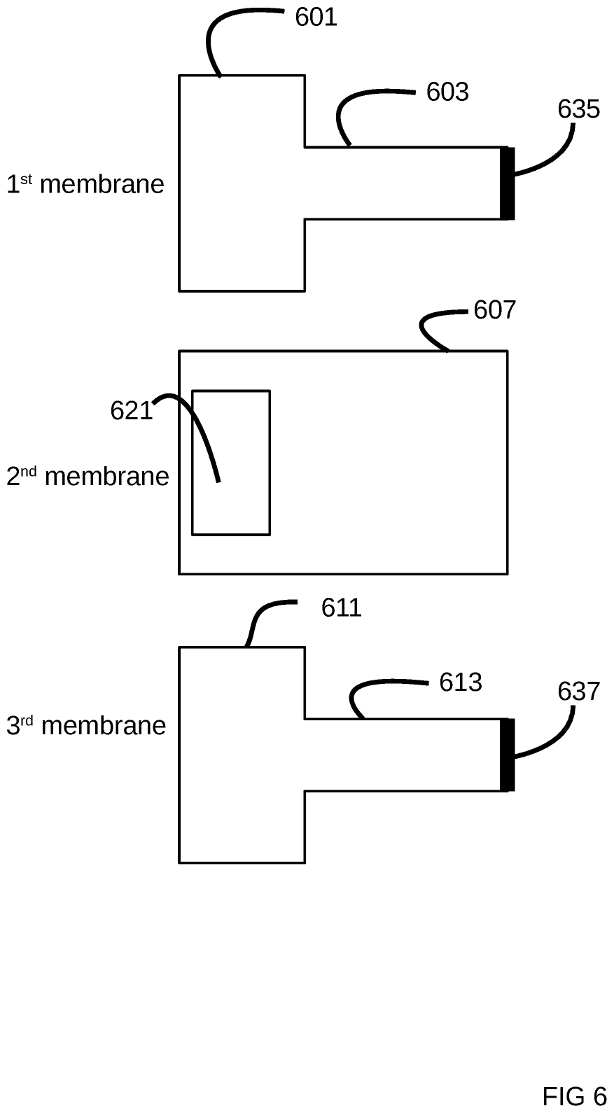

FIG. 6 is an alternative example of the configuration of three layers for a cell of an ultrasonic pump. The layers include but are not limited to; a first membrane (601) and spoke (603) comprising a first layer; a second membrane (607) configured with at least one aperture (621) comprising a second layer; a third membrane (611) and spoke (613) comprising a third layer. The layers are aligned so that there is overlap between first and third membrane (601, 611) and aperture (621), where the minimum overlap distance is as defined previously. In a further example, spoke (603) is connected to a first anchor (635) and is except for anchor (635) free to move. Spoke (613) is connected to a first anchor (637) and is except for anchor (637) free to move. In this example, since the membrane is asymmetrically anchored the movement will be asymmetric with the area of the membrane furthest from the anchor moving the most. In a further example location of aperture (621) is configured to provide the smallest overlap at the area of the membrane furthest from the anchor. In one example the overlap at the furthest location of the membrane is termed effective overlap and is at least but not limited to; 100 nm; 1 micron; 5 micron; 10 micron; 100 micron; less than 1 mm. Overlap at other locations are blocking overlaps and are at least 2 times larger than the effective overlap.

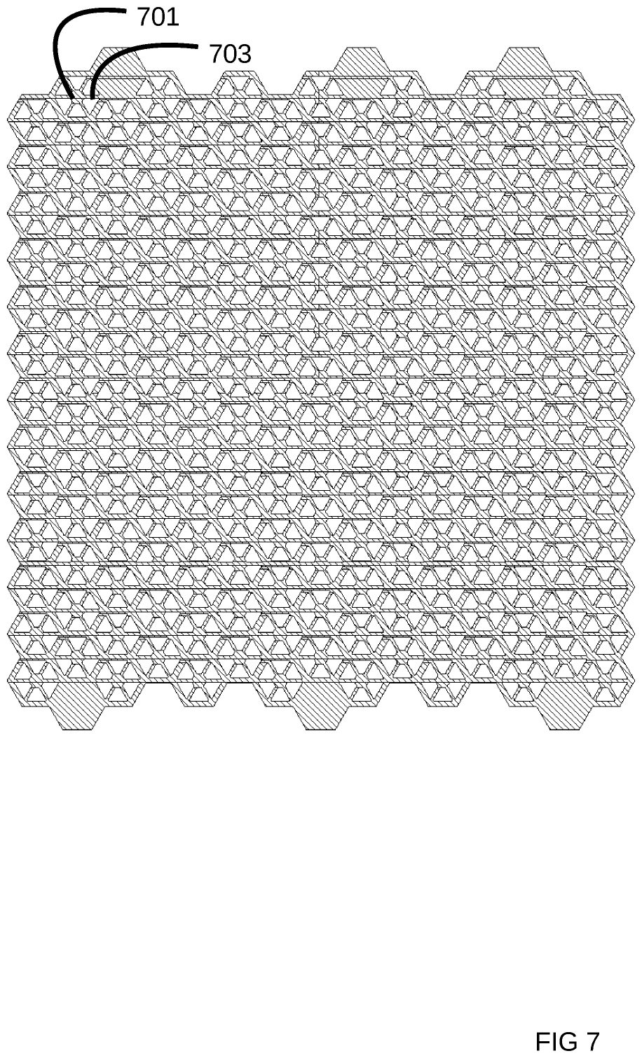

FIG. 7 is an example of top view of an array configured of a plurality of cells of FIG. 1A. A cell includes a membrane (701) and at least one spoke (703). Example of cell arrangement include but are not limited to; rectangle; square; circle. A ultrasonic pump comprises one or more cells where a cell can be actuated individually or in conjunction with one or more cells.

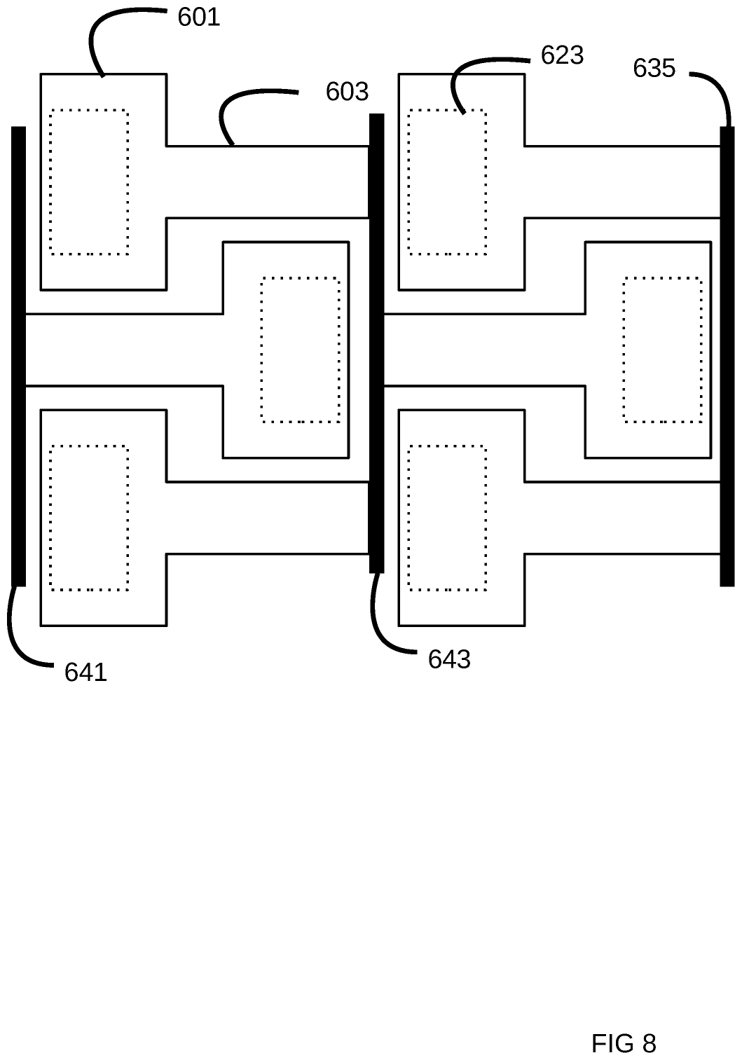

FIG. 8 is an example of a top view of an array configured of a plurality of cells of FIG. 6. A cell includes a membrane (601), a spoke (603). Aperture is depicted as a dashed rectangle (621). Spoke (603) is attached to anchor (635). Second anchor (641, 643) is an example for connecting a second group of spokes.

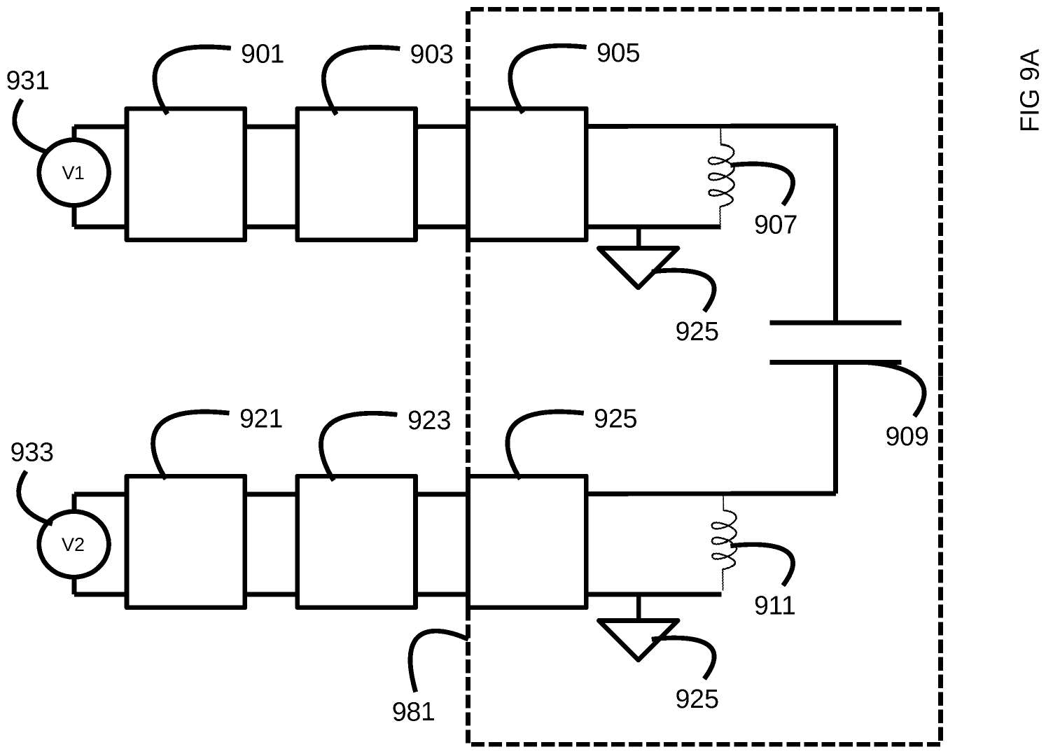

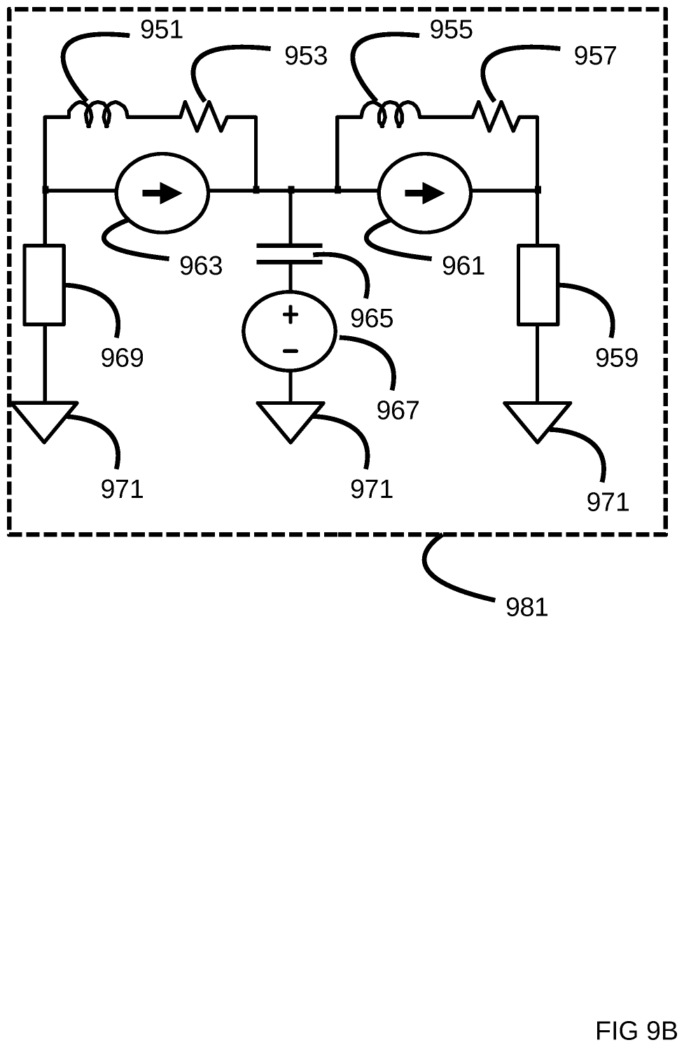

FIG. 9A is an example of a two port or lumped element representation of the ultrasonic pump. This is an alternative representation of equations (7) to (10). In a lumped element model acoustic or fluidic pressure is represented as a voltage, acoustic or fluidic flow is represented as a current, and passive components such as capacitors, resistors, and inductors represent compliance, acoustic flow resistance, and inertia of air or fluid respectively. The two port or lumped element model is used to describe electrical and mechanical aspects of a membrane. The electrical part of the model uses the standard conventions for electric elements and connects a mechanical movement of the membrane as voltage or current element. Hence in case of an electrostatic membrane, the charge on the device would increase as a function of the membrane movement towards the ground representing the pull-in phenomena. The mechanical portion of the model connects the electrostatic force represented as a voltage, the compliance of the membrane represented as a capacitor, the mass of the membrane represented as an inductor, and the damping represented as a resistor. The resulting membrane speed is represented by the current and the displacement is represented by the accumulated charge. The membrane speed is used to calculate the airflow, and the membrane movement to calculate the resistance and inductance of the respective acoustic channels and capacitance is the distance between the membranes. The pressure on the membranes is represented as a pressure dependent voltage source. Two port models have two ports connecting the model units and can be represented as a matrix multiplication. We adopt a common two port model for the description of a first membrane comprising of a first voltage source (931) a first electrical two port (901) coupled to a first mechanical two port (903) and coupled to a first acoustic two port (905). The coupled two ports describe the acoustic output generated by a first voltage source (931). A first electrical two port (901) includes at least but is not limited to a capacitance, an inductance, a resistance and describes the relation between an applied voltage on the membrane and the resulting current. A first mechanical two port (903) describes the relation between an applied voltage on the membrane and the membrane movement and includes lumped elements representing the compliance (capacitance), inertia (inductor), and mechanical loss (resistance). The model describes an electrostatic or piezo electric drive. For electromagnetic drive, the membrane movement is proportional to the current in the first electrical two port. The voltage represents the membrane displacement and the current represents the membrane speed. A first acoustic two port (905) describes the relation between membrane movement and air flow and includes lumped elements representing the compliance (capacitance), inertia (inductor), and viscous or thermal loss (resistance). A second membrane is described in similar manner with a second electrical two port (921) coupled to a second mechanical two port (923) coupled to a second acoustic two port (925). The first and second membrane are connected to a common volume represented by chamber capacitor (909) and connected to the surrounding medium represented by a ground symbol (925) through an acoustic channel represented as channel inductor (907, 911). Chamber capacitor is a voltage dependent capacitor where the capacitance value is determined by the volume of air (FIG. 1B 127) defined by first (FIG. 1B 101), second (FIG. 1B 111), and third membrane (FIG. 1B 107). Displacement of the membranes is represented by first and second mechanical two port voltage (903, 923) and chamber capacitor (909) capacitance is tied to membrane displacement. A first channel inductor (907) is a voltage dependent inductor, where the inductance is a function of a first membrane displacement as this affects the channel dimension and the inertance and resistance. Similarly, second channel inductor (911) inductance is a function of a second membrane displacement as this affects the channel dimension and the inertance and resistance. Hence the first and channel inductor (907, 911) are dependent on the first and second membrane displacement.

FIG. 9B is an example of a lumped element description of the acoustic module of the ultrasonic pump (981, in FIG. 9A). In one example the acoustic module includes at least but not limited to a current source (963, 961) corresponding to the airflow from the respective membrane (903, 923) speed, at least two acoustic channels each comprised of at least a resistor (953, 957) and inductor (951, 955), where the resistor (953, 957) and inductor (951, 955) values are dependent on the respective membrane (903, 923) displacement; and a capacitor (965) representing the air volume between the membranes (903, 923). The air volume between the membranes (903, 923) changes as a function of membrane (903, 923) displacement and generates airflow. As elucidated by the description in FIG. 9B, the total airflow from the ultrasonic pump includes at least three elements; airflow from movement of a first membrane (903); airflow from movement of a second membrane (923); and airflow from the compression or expansion of volume between the membranes (903, 923). An important feature is the addition of the bias pressure (967). In acoustic lumped element analysis, the DC pressure is implicitly taken as 0 and the resulting equations find the pressure difference in comparison to 0. In reality the 0 of the equations corresponds to atmospheric pressure. For a time, varying volume (capacitor—965) to generate flow, the bias needs to be accounted hence we add the bias pressure (967) which describes the atmospheric pressure in the volume between the membranes. The acoustic channel comprises the modulator aspect of the ultrasonic pump. Acoustic loads (959, 969) represent the acoustic load of the first and second membrane (903, 923) and acoustic channels. Acoustic loads include but are not limited to, resistors as common in meshes, capacitors as common in closed volumes, or inductors as common in air flow. In one example an acoustic load is a occluded or semi occluded volume as typically used to represent an ear, in another example the acoustic load is a horn or acoustic tube, and in another example the acoustic load is radiation into air or baffle. The description of the ultrasonic pump and previous descriptions apply for any fluid including but not limited to air, gases, liquids, water, salt water, mineral or organic oils and their combinations.

To summarize we describe an ultrasonic pump comprised of; a first layer with at least one membrane, at least one spoke and at least one anchor, wherein first layer membrane is in contact with at least one spoke and said spoke is in contact with at least one anchor; a second layer with at least one membrane and at least one anchor wherein second layer membrane is in contact with a second layer anchor and second layer membrane includes at least one aperture; a third layer with at least one membrane, at least one spoke and at least one anchor, wherein third layer membrane is in contact with at least one spoke and said spoke is in contact with at least one anchor; wherein first, second and third membrane are vertically stacked and wherein the height between first, second and third layers is defined by the respective anchor height; and wherein first layer at least one membrane and third layer at least one membrane are actuated to generate fluid flow. In a further example a membrane and spoke of first or third layer is comprised of any but not limited to; conductive material; piezo electric material; electrically resistive material. In a further example a membrane and spoke of first or third layer is comprised of any but not limited to; Al; Au; Ag; Ni; PZT; AlN; AlScN; AlOx; TiO2; Si; polySi; KNN or combinations of these materials. In a further example a membrane and spoke of first or third layer is actuated using; electrostatic; piezo electric or thermoelectric actuation. In a further example an anchor is comprised of at least but not limited to one material of; SiO2; polymer; TiO2; AlN; W; SiN or combinations of these materials. In a further example a first layer membrane, third layer membrane and second layer aperture are aligned wherein the overlap between the second layer aperture and first- or third-layer membrane is larger than any of but not limited to 100 nanometer, 1 micron, 5 micron, 10 micron, 50 micron. In a further example the actuation of the first layer at least one more membrane or actuation of third layer at least one membrane is any of but not limited to, harmonic, quasi harmonic, narrow band modulated, periodic, nonperiodic. In a further example the actuation of the first layer at least one membrane or actuation of third layer at least one membrane is any of but not limited to, harmonic, quasi harmonic, narrow band modulated, periodic and the actuation of first layer at least one membrane is phase delayed in reference to third layer at least one membrane. In a further example the phase is any of but not limited to 900 or 2700 or any other phase between −1800 to 1800. In a further example the actuation of the first layer at least one more membrane or actuation of third layer at least one membrane is any of but not limited to; harmonic; quasi harmonic; narrow band modulated; periodic, and wherein actuation of first layer at least one membrane and actuation of third layer at least one membrane comprising of at least one non overlapping frequency component. In a further example the actuation of the first layer at least one more membrane or actuation of third layer at least one membrane is configured to generate a time varying fluid flow. In a further example the time varying fluid flow can vary at any rate from constant flow to at least 50,000 Hz or at least 100,000 Hz or at least 500,000 Hz. In a further example the actuation of the first layer at least one more membrane or actuation of third layer at least one membrane is any of but not limited to; harmonic; quasi harmonic; narrow band modulated; periodic and configured as a volume velocity acoustic source. In an alternative example an ultrasonic pump comprising; a first membrane; a second membrane configured with an aperture; a third membrane; wherein a first, second and third membrane are vertically stacked and a first membrane and or a third membrane overlap a portion of the aperture of a second membrane and wherein the a first membrane and or a third membrane are actuated independently to move at ultrasonic rates and induce fluid flow. In an alternative further example, the ultrasonic pump further comprised of a volume of fluid at least partially enclosed by first and third membrane and providing a fluidic coupling between first and third membrane. In a further example to both previous examples the ultrasonic pump comprises a plurality of first, second and third membranes. In a further example a membrane is comprised of any but not limited to; conductive material; piezo electric material; electrically resistive material. In a further example a membrane is comprised of any but not limited to; Al; Au; Ag; Ni; PZT; AlN; AlScN; AlOx; TiO2; Si; polySi; KNN or combinations of these materials. In a further example a membrane is actuated using; electrostatic; piezo electric or thermoelectric actuation. In a further example the overlap between a first membrane, a third layer membrane and second membrane aperture is larger than any of but not limited to 100 nanometer, 1 micron, 5 micron, 10 micron, 50 micron. In a further example the actuation of a first membrane or second membrane or a third membrane is any of but not limited to, harmonic, quasi harmonic, narrow band modulated, periodic, nonperiodic. In a further example the actuation of any off but not limited to a first membrane, a second membrane, a third membrane or combinations of membranes is any of but not limited to, harmonic, quasi harmonic, narrow band modulated, periodic and the actuation of one membrane is phase delayed in reference to another membrane. In a further example the phase is any of but not limited to 900 or 2700 or any between −1800 and 1800. In a further example the actuation of any off but not limited to a first membrane, a second membrane, a third membrane or combinations of membranes is any of but not limited to; harmonic; quasi harmonic; narrow band modulated; periodic, and wherein actuation of any two membranes includes at least one non overlapping frequency component. In a further example the actuation of any off but not limited to a first membrane, a second membrane, a third membrane or combinations of membranes is configured to generate a time varying fluid flow. In a further example the time varying fluid flow can vary at any rate from constant flow to at least 50,000 Hz or at least 100,000 Hz or at least 500,000 Hz. In a further example the actuation of any off but not limited to a first membrane, a second membrane, a third membrane or combinations of membranes is any of but not limited to; harmonic; quasi harmonic; narrow band modulated; periodic and configured as a volume velocity acoustic source. In an alternative example an ultrasonic pump is represented as a lumped element model comprised of at least two membranes; a current source corresponding to the speed and area of each of the membranes; an inductor with an inductance determined by the acoustic channel defined by a membrane and a reference structure or membrane; a resistor with a resistance determined by the acoustic channel defined by a membrane and a reference structure or membrane; a capacitor with a capacitance defined by the volume defined by at least two membranes; wherein a resistor and an inductor are connected in series and current sources, capacitors and inductor resistor pairs have a common connection corresponding to the cavity defined by at least two membranes and wherein a movement of at least two membranes generates a current flow where at least a portion of flow corresponds to multiplication of a movement of first membrane and movement of second membrane.

There is little distinction left between hardware and software implementations of aspects of systems; the use of hardware or software is generally (but not always, in that in certain contexts the choice between hardware and software can become significant) a design choice representing cost versus efficiency tradeoffs. There are various vehicles by which processes and/or systems and/or other technologies described herein can be affected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; if flexibility is paramount, the implementer may opt for a mainly software implementation; or, yet again alternatively, the implementer may opt for some combination of hardware, software, and/or firmware.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, or examples can be implemented, individually and/or collectively, by a wide range of hardware, software, firmware, or virtually any combination thereof. In one embodiment, several portions of the subject matter described herein may be implemented via Application Specific Integrated Circuits (ASICs), Field Programmable Gate Arrays (FPGAs), digital signal processors (DSPs), or other integrated formats. However, those skilled in the art will recognize that some aspects of the embodiments disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and or firmware would be well within the skill of one of skill in the art in light of this disclosure. In addition, those skilled in the art will appreciate that the mechanisms of the subject matter described herein are capable of being distributed as a program product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a floppy disk, a hard disk drive, a Compact Disc (CD), a Digital Versatile Disk (DVD), a digital tape, a computer memory, etc.; and a transmission type medium such as a digital and/or an analog communication medium (e.g., a fiber optic cable, a waveguide, a wired communications link, a wireless communication link, etc.).

Those skilled in the art will recognize that it is common within the art to describe devices and/or processes in the fashion set forth herein, and thereafter use engineering practices to integrate such described devices and/or processes into data processing systems. That is, at least a portion of the devices and/or processes described herein can be integrated into a data processing system via a reasonable amount of experimentation. Those having skill in the art will recognize that a typical data processing system generally includes one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors (e.g., feedback for sensing position and/or velocity; control motors for moving and/or adjusting components and/or quantities). A typical data processing system may be implemented utilizing any suitable commercially available components, such as those typically found in data computing/communication and/or network computing/communication systems.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to disclosures containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”. Speaker and picospeaker are interchangeable and can be used in in place of the other.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. An ultrasonic pump comprising:
a first layer with at least one membrane, at least one spoke and at least one anchor, wherein at least one membrane is in contact with at least one spoke and the spoke is in contact with at least one anchor;
a second layer with at least one second membrane and at least one second anchor wherein the second membrane is in contact with a second anchor and the second membrane includes at least one aperture;
a third layer with at least one third membrane, at least one third spoke and at least one third anchor, wherein third membrane is in contact with at least one third spoke and said third spoke is in contact with at least one third anchor;
wherein the first, second and third membrane are vertically stacked and wherein the height between the first, second and third layers is defined by the respective anchor height; and
wherein the first layer at least one membrane and the third layer at least one membrane are configured to be actuated to generate fluid flow.

2. The ultrasonic pump of claim 1 configured as a centrifugal pump.

3. The ultrasonic pump of claim 1 wherein a membrane and spoke of the first or third layer comprise of any of: conductive material; piezo electric material; electrically resistive material.

4. The ultrasonic pump of claim 1 wherein a membrane and spoke of first or third layer is configured to be actuated using: electrostatic; piezo electric or thermoelectric actuation.

5. The ultrasonic pump of claim 1 wherein the first layer membrane, third layer membrane and second layer aperture are aligned wherein the overlap between the second layer aperture and first or third layer membrane is larger than any of but not limited to: 100 nanometer, 1 micron, 5 micron, 10 micron, 50 micron.

6. The ultrasonic pump of claim 1 wherein the actuation of the first layer at least one membrane or actuation of the third membrane is: harmonic, quasi harmonic, narrow band modulated, periodic, nonperiodic.

7. The ultrasonic pump of claim 1 wherein the actuation of the first layer at least one membrane or actuation of third membrane is any of: harmonic, quasi harmonic, narrow band modulated, periodic and the actuation of first layer at least one membrane is phase delayed in reference to the third membrane, wherein the phase is 90° or 270°.

8. The ultrasonic pump of claim 1 wherein the actuation of the first layer at least one membrane or actuation of the third membrane is any of: harmonic; quasi harmonic; narrow band modulated; periodic, and wherein actuation of first layer at least one membrane and actuation of third layer at least one membrane comprising of at least one non overlapping frequency component.

9. The ultrasonic pump of claim 1 wherein the actuation of the first layer at least one membrane or actuation of third membrane is configured to generate a time varying fluid flow that can vary at any rate from constant flow to at least 50,000 Hz.

10. An ultrasonic pump comprising:
a first membrane;
a second membrane configured with an aperture; and
a third membrane,
wherein the first, second and third membranes are vertically stacked and a first membrane and or a third membrane overlap a portion of the aperture of the second membrane, and
wherein the first membrane and/or the third membrane is configured to be actuated independently to move at ultrasonic rates and induce fluid flow.

11. The ultrasonic pump of claim 10 configured as a centrifugal pump.

12. The ultrasonic pump of claim 10 wherein the ultrasonic pump comprises a plurality of first, second and third membranes.

13. The ultrasonic pump of claim 10 wherein the first, second or third membrane comprises any of: conductive material; piezo electric material; electrically resistive material.

14. The ultrasonic pump of claim 10 wherein an overlap between a first membrane, the third membrane and second membrane aperture is larger than any of: 100 nanometer, 1 micron, 5 micron, 10 micron, 50 micron.

15. The ultrasonic pump of claim 10 wherein the actuation of any of the first membrane, the second membrane, the third membrane or combinations of membranes is any of: harmonic, quasi harmonic, narrow band modulated, periodic and the actuation of one membrane is phase delayed in reference to another membrane, wherein the phase is 90° or 270°.

16. The ultrasonic pump of claim 10 wherein the actuation of any of the first membrane, the second membrane, the third membrane or combinations of membranes is configured to generate a time varying fluid flow that can vary at any rate from constant flow to at least 50,000 Hz.

17. The ultrasonic pump of claim 15 wherein the actuation of any of the first membrane, the second membrane, the third membrane or combinations of membranes is any of: harmonic; quasi harmonic; narrow band modulated; periodic and configured as a volume velocity acoustic source.

18. An ultrasonic pump comprising:
a first membrane;
a second membrane configured with an aperture;
a third membrane,
wherein the first, second and third membranes are vertically stacked and the first membrane and/or the third membrane overlap a portion of the aperture of a second membrane; and
a volume of fluid at least partially enclosed by the first and third membrane providing a fluidic coupling between the first and third membrane, and wherein the first membrane and/or the third membrane are configured to be actuated independently to move at ultrasonic rates, and induce fluid flow.

19. The ultrasonic pump of claim 18 configured as a centrifugal pump.

20. The ultrasonic pump of claim 18 wherein the ultrasonic pump comprises a plurality of first, second and third membranes.

21. The ultrasonic pump of claim 18 wherein each membrane comprises of any of: conductive material; piezo electric material; electrically resistive material.

22. The ultrasonic pump of claim 18 wherein each membrane is configured to be actuated using: electrostatic; piezo electric or thermoelectric actuation.

23. The ultrasonic pump of claim 18 wherein an overlap between the first membrane, the third layer membrane and the second membrane aperture is larger than any of: 100 nanometer, 1 micron, 5 micron, 10 micron, 50 micron.

24. The ultrasonic pump of claim 18 wherein the actuation of any of the first membrane, the second membrane, the third membrane or combinations of membranes is any of: harmonic, quasi harmonic, narrow band modulated, periodic and the actuation of one membrane is phase delayed in reference to another membrane, wherein the phase is 90° or 270°.

25. The ultrasonic pump of claim 18 wherein the actuation of the first membrane, the second membrane, the third membrane or combinations of membranes is any of: harmonic; quasi harmonic; narrow band modulated; periodic, and wherein actuation of any two membranes includes at least one non overlapping frequency component.

26. The ultrasonic pump of claim 18 wherein the actuation of any of the first membrane, the second membrane, the third membrane or combinations of membranes is configured to generate a time varying fluid flow that can vary at any rate from constant flow to at least 50,000 Hz.

27. The ultrasonic pump of claim 18 wherein the actuation of any of the first membrane, the second membrane, the third membrane or combinations of membranes is any of: harmonic; quasi harmonic; narrow band modulated; periodic and configured as a volume velocity acoustic source.

28. An ultrasonic pump represented as a lumped element model comprising:
at least two membranes;
a current source corresponding to a speed and area of each of the membranes;
an inductor with an inductance determined by an acoustic channel defined by a membrane and a reference structure or membrane;
a resistor with a resistance determined by the acoustic channel;
a capacitor with a capacitance defined by a volume defined by the at least two membranes;
wherein the resistor and the inductor are connected in series and current sources, capacitors and inductor resistor pairs have a common connection corresponding to a cavity defined by at the least two membranes, and
wherein a movement of at least two membranes generates a current flow where at least a portion of flow corresponds to multiplication of a movement of a first membrane and movement of a second membrane.
